(19) United States
(12) Patent Application Publication
(10) Pub. No.: US 2025/0342135 A1
(43) Pub. Date: Nov. 6, 2025

(54) APPARATUS AND METHODS FOR MULTI-MEMORY CONFIGURATION SUPPORT WITHIN DIE ARCHITECTURES AND PACKAGING

(71) Applicant: QUALCOMM Incorporated, San Diego, CA (US)

(72) Inventors: Vivek MOHAN, San Diego, CA (US); Boris Dimitrov ANDREEV, San Diego, CA (US); Vaishnav SRINIVAS, Oceanside, CA (US); Piyush GUPTA, San Diego, CA (US)

(21) Appl. No.: 18/652,700

(22) Filed: May 1, 2024

(51) Int. Cl. G06F 15/78; H01L 25/065; H10B 80/00

(52) U.S. Cl. CPC G06F 15/7807; H01L 25/0652; H10B 80/00

(57) ABSTRACT

Methods and apparatuses for on-die logic that allow dies, such as a system-on-a-chips (SoCs), to support multiple memory devices in various die configurations. In one example, a die package comprises a first memory device and a system-on-a-chip (SoC). The SoC includes a first plurality of physical layer interfaces electrically connected to the first memory device, wherein the SoC and the first memory device are in a first die package configuration. The SoC also includes a second plurality of physical layer interfaces configured to electrically connect to a second memory device, wherein the SoC and the second memory device are in a second die package configuration In some instances, the first die package configuration is package-on-package (POP), and the second die configuration is system-in-a-package (SiP).

### BACKGROUND

### Field of the Disclosure

This disclosure relates generally to die architectures and packaging and, more specifically, to memory configurations within die architectures and packaging.

### Description of Related Art

Die packages often include dies, such as systems-on-a-chip (SoCs), embedded within a substrate. Die packages may be used across a multitude of applications, such as telecommunication, automotive, cloud-based, gaming, enterprise, and networking applications, among various other applications. The dies within a die package often require connections to memory devices. The memory devices may be located within the same die package, or may be located outside the die package. For example, products often require SoCs with a particular memory configuration. Indeed, a specific memory configuration is often decided on at an early stage of a project. As a result, SoCs are often designed and manufactured for each of various memory configurations that may be required by a project, thereby leading to multiple versions of a particular SoC and/or die package. As such, there are opportunities to address these and other deficiencies associated with die architectures and packaging.

### SUMMARY

According to one aspect, a die package comprises a first memory device and a system-on-a-chip (SoC). The SoC includes a first plurality of physical layer interfaces electrically connected to the first memory device, wherein the SoC and the first memory device are in a first die package configuration. The SoC also includes a second plurality of physical layer interfaces configured to electrically connect to a second memory device, wherein the SoC and the second memory device are in a second die package configuration.

According to another aspect, a die package comprises a first memory device, a second memory device, and a system-on-a-chip (SoC). The SoC includes a first plurality of physical layer interfaces electrically connected to the first memory device, wherein the SoC and the first memory device are in a first die package configuration. The SoC also includes a second plurality of physical layer interfaces electrically connected to the second memory device, wherein the SoC and the second memory device are in a second die package configuration. Further, the SoC is configured to provide power to the first plurality of physical layer interfaces and the second plurality of physical layer interfaces over at least one power rail.

According to yet another aspect, a system-on-a-chip (SoC) includes a first plurality of physical layer interfaces configured to electrically connect to a first memory device when the SoC and the first memory device are in a first die package configuration. The SoC also includes a second plurality of physical layer interfaces configured to electrically connect to a second memory device when the SoC and the second memory device are in a second die package configuration. Further, the SoC is configured to provide power to the first plurality of physical layer interfaces and the second plurality of physical layer interfaces over at least one power rail.

According to even another aspect, a system-on-a-chip (SoC) includes a first plurality of physical layer interfaces configured to electrically connect to a first memory device when the SoC and the first memory device are in a first die package configuration. The SoC also includes a second plurality of physical layer interfaces configured to electrically connect to a second memory device when the SoC and the second memory device are in a second die package configuration. Further, the SoC includes a processor configured to generate and transmit power regulator data to a power control device, the power data causing the power control device to enable power to at least one of the first plurality of physical layer interfaces and the second plurality of physical layer interfaces.

### BRIEF DESCRIPTION OF DRAWINGS

FIG. 1 is a block diagram of an integrated circuit, according to some implementations;

FIGS. 2A and 2B are block diagrams of exemplary die packages, according to some implementations;

FIG. 3 is a block diagram of a die package, according to some implementations;

FIG. 4 is a block diagram of a die package, according to some implementations;

FIGS. 5A, 5B, 5C, 5D, and 5E are block diagrams of exemplary system-on-a-chips in communication with power management integrated circuits, according to some implementations;

FIG. 6 is a block diagram of an exemplary system-on-a-chip in communication with a power management integrated circuit, according to some implementations; and

FIG. 7 is a block diagram of a system-on-a-chip, according to some implementations.

### DETAILED DESCRIPTION

While the features, methods, devices, and systems described herein may be embodied in various forms, some exemplary and non-limiting embodiments are shown in the drawings, and are described below. Some of the components described in this disclosure are optional, and some implementations may include additional, different, or fewer components from those expressly described in this disclosure.

The embodiments described herein are directed to on-die logic that allows a die, such as a system-on-a-chip (SoC), to support multiple memory devices in various die configurations. These die configurations can include, for example, system-in-a-package (SiP), package-on-package (POP), universal flash storage (UFS), and UFS-based multichip package (uMCP) die configurations. Among other advantages, the embodiments can provide dies with an increased number of communication channels, thereby allowing the dies to increase memory communication bandwidths. In addition, the embodiments can prevent or reduce the manufacturing of dies in various configurations. For instance, the embodiments may allow for the manufacturer of dies in just one configuration while still supporting memory devices in various die configurations. As a result, the embodiments may reduce the cost and complexity associated with manufacturing dies in various die configurations.

For instance, in some examples, a die package includes a memory device and an SoC. The memory device may be, for example, a dynamic access random memory (DRAM), static random-access memory (SRAM), FLASH (e.g., UFS), uMCP, or any other suitable memory device. The SoC includes multiple physical layer interfaces that electrically connect to the memory device. For instance, the SoC may include four physical layer interfaces, where each physical layer interface includes a number of input/output lines (e.g., 24) that are clocked at a particular clock rate (e.g., 5.3 Gigabytes/second). Further, the SoC and the first memory device may be in a particular die package configuration. For instance, the SoC and the first memory device may be in a system-in-a-package (SiP) configuration, where the first memory device and the SoC are in a side-by-side or vertical configuration within a same die package.

The SoC also includes additional physical layer interfaces that can be electrically connected to a second memory device when, for example, the SoC and the second memory device are in another die package configuration. For instance, the additional physical layer interfaces may allow for an electrical connection to a second memory device that is external to the die package of the SoC, such as when the second memory device is in a PoP die configuration with the SoC. As an example, the SoC may include two additional physical layer interfaces (e.g., for a total of six physical layer interfaces) that allow for access to a second memory device that is situated atop the SoC in a POP die configuration.

In some examples, the SoC is configured to provide power to the physical layer interfaces over at least one power rail. For example, the SoC may provide a power rail that provides power to the four SiP physical layer interfaces and the two PoP physical layer interfaces. In other examples, the SoC may provide a first power rail that provides power to the four SiP physical layer interfaces, and a second power rail that provides power to the two POP physical layer interfaces. The power rails may receive power from, for example, a power management integrated circuit (PMIC). In some instances, one or more pins of the SoC may correspond to the power rails. In some configurations, at least one of the pins corresponding to a power rail may be left unconnected (e.g., floating), causing the corresponding physical layer interfaces to be disabled. In other configurations, at least one of the pins corresponding to a power rail may be electrically connected to ground, causing the corresponding physical layer interfaces to be disabled.

In some examples, the SoC includes a processor (e.g., a microcontroller, central processing unit (CPU), graphical processing unit (GPU), processing core, etc.) that is configured to generate and transmit power data to a power control device, such as a power management integrated circuit (PMIC). The power data causes the power control device to enable or disable power to one or more of the physical layer interfaces. For example, the power control device may include a regulator that is electrically connected, and provides power, to a power rail for one or more of the physical layer interfaces. The processor may generate and transmit power data to the power control device that causes the power control device to enable, or disable, the regulator.

In some instances, the power control device may include a first regulator that can provide power to a first plurality of physical interface layers over a first power rail, and a second regulator that can provide power to a second plurality of physical interface layers over a second power rail. The processor may generate and transmit first power data to the power control device. Based on the first power data, the power control device may enable, or disable, the first regulator. For example, the power control device may write the first power data to a register that controls whether the first regulator is enabled or disabled. When the first regulator is enabled, the first regulator provides power over the first power rail to the first plurality of physical interface layers. When the first regulator is disabled, the first regulator removes (e.g., cuts) power to the first power rail Similarly, the processor may generate and transmit second power data to the power control device. Based on the second power data, the power control device may enable, or disable, the second regulator.

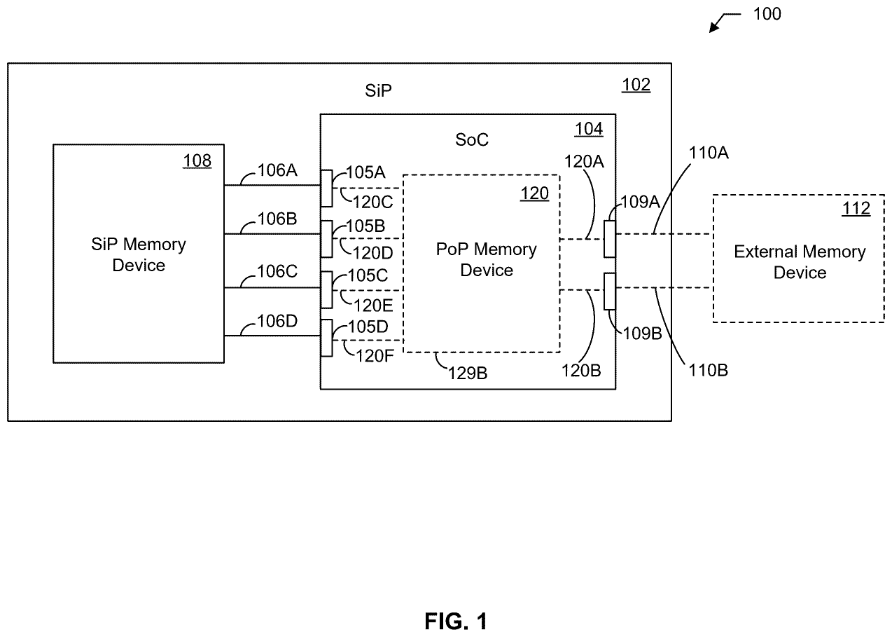

Referring now to the figures, FIG. 1 illustrates a block diagram of an integrated circuit 100 that includes a system-in-a-package (SiP) 102 electrically coupled to, optionally, one of an external memory device 112 and a package-on-a-package (POP) memory device 120. As illustrated, the SiP 102 includes a system-on-a-chip (SoC) 104 and a SiP memory device 108. Each of the SiP memory device 108, optional external memory device 112, and optional external memory device 112 may be, for example, a DRAM, SRAM, FLASH, uMCP, or any other suitable memory device.

SoC 104 includes multiple physical layer interfaces (i.e., PHYs) including PHY 105A, PHY 105B, PHY 105C, PHY 105D, PHY 109A, and PHY 109B. Although six physical layer interfaces are illustrated, in other examples, SoC 104 may include more than six physical layer interfaces. Each of these physical layer interfaces can include corresponding signals, such as transmit, receive, address, control, and/or clock signals. For instance, each of these physical layer interfaces can be, for instance, an Ethernet, USB, USB 2.0, I²C, SPI, DDR 4 SDRAM, DDR5 SDRAM, or any other suitable physical layer interface. Moreover, the physical layer interfaces can each be configured to operate as separate communication channels, or can be combined with one or more other physical layer interfaces to operate collectively as one communication channel (e.g., PHYs 105A, 105B, 105C, and 105D may operate together as one communication channel, where each of the physical layer interfaces provide a portion (e.g., 25%) of the channel data bandwidth).

In this example, each of the PHYs 105A, 105B, 105C, and 105D are electrically connected to SiP memory device 108 over corresponding communication links 106A, 106B, 106C, and 106D, thereby providing four corresponding communication channels between the SoC 104 and the SiP memory device 108. PHYs 105A, 105B, 105C, and 105D may be, for instance, optimized for SiP 102 communications (e.g., data transfers) with SiP memory device 108.

In some examples, integrated circuit 100 includes POP memory device 120 that may be positioned (e.g., soldered) atop the SoC 104. In some of these examples, PHYs 109A and 109B may be electrically connected to POP memory device 120 over corresponding communication links 120A and 120B, thereby providing two corresponding communication channels between the SoC 104 and the POP memory device 120. For instance, the POP memory device 120 may include solder balls (e.g., ball grid array (BGA)) that are soldered to the communication links 120A and 120B atop the SoC 104. In some examples, rather than being electrically coupled to SiP memory device 108 over communication links 106A, 106B, 106C, and 106D, one or more of PHYs 105A, 105B, 105C, and 105D may be electrically connected to POP memory device 120 over corresponding communication links 120C, 120D, 120E, and 120F, thereby providing up to four communication channels between the SoC 104 and the POP memory device 120. For instance, PHYs 105A, 105B may be electrically coupled to communication links 106A, 106B, and PHYs 105C, 105D may be electrically coupled to communication links 120E, 120F.

In other examples, integrated circuit 100 includes external memory device 112. In these examples, PHYs 109A and 109B may be electrically connected to external memory device 112 over corresponding communication links 110A and 110B, thereby providing corresponding communication channels between the SoC 104 and the external memory device 112. As such, in this configuration, SoC 104 can simultaneously support communications with SiP memory device 106 and external memory device 112.

Moreover, regardless of whether the integrated circuit 100 includes PoP memory device 120 or external memory device 112, the same SoC 104 can support both configurations. Indeed, SiP 102 can be manufactured to include SoC 104 and SiP memory device 108 as illustrated, and can then be used in designs that prefer or require POP memory device 120 as well as in designs that prefer or require external memory device 112.

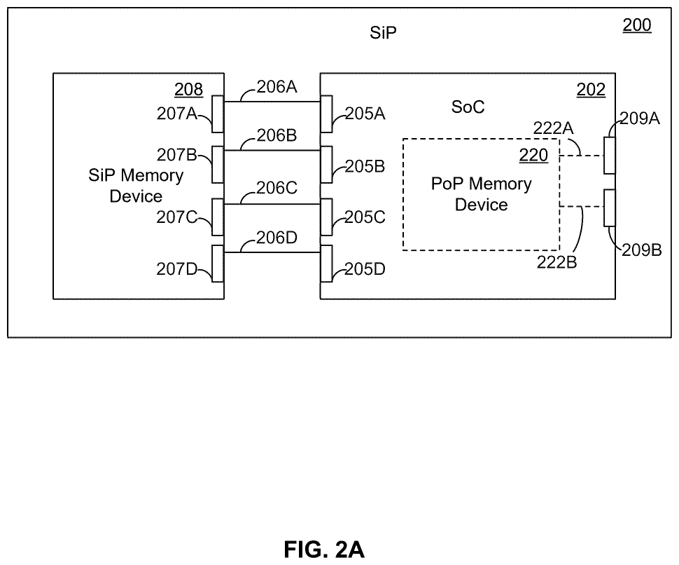

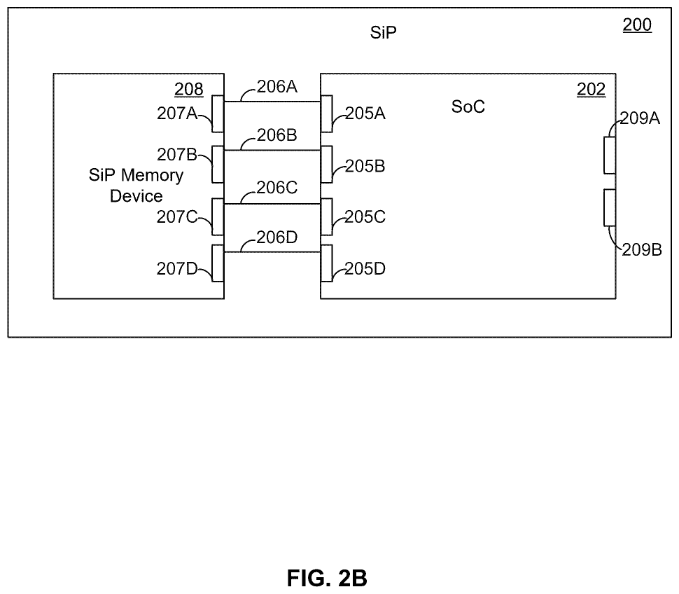

FIGS. 2A and 2B illustrate a SiP 200 in various configurations. For example, as illustrated in FIG. 2A, SiP 200 includes an SoC 202 electrically connected to SiP memory device 208. SiP memory device 208 may be any suitable memory device, such as a DRAM, SRAM, FLASH, uMCP, or any other suitable memory device. Further, SoC 202 includes six physical layer interfaces including PHYs 205A, 205B, 205C, 205D, 109A, and 209B. In this example, each of the PHYs 205A, 205B, 205C, 205D are electrically connected to SiP memory device 208 over corresponding communication links 206A, 206B, 206C, and 206D, thereby providing four corresponding communication channels between the SoC 202 and the SiP memory device 208. More specifically, PHY 205A of SoC 202 is electrically connected to a PHY 207A of the SiP memory device 208 over communication link 206A. Similarly, PHY 205B of SoC 202 is electrically connected to a PHY 207B of the SiP memory device 208 over communication link 206B. In addition, PHY 205C of SoC 202 is electrically connected to a PHY 207C of the SiP memory device 208 over communication link 2060, and PHY 205D of SoC 202 is electrically connected to a PHY 207D of the SiP memory device 208 over communication link 206D,

In this example, POP memory device 220 is mounted atop the SoC 202. For instance, the POP memory device 220 may include solder balls (e.g., BGAs) that are soldered to communication links 222A and 222B atop the SoC 202. Further, SoC 202 includes PHYs 209A and 209B that are electrically connected to POP memory device 220 over the communication links 122A and 122B, respectively, thereby providing two corresponding communication channels between the SoC 202 and the POP memory device 220. As such, in this example, SoC 202 simultaneously supports communications with SiP memory device 208 and POP memory device 220. For instance, SoC 202 may simultaneously transfer data (e.g., read data, write data) with SiP memory device 208 and POP memory device 220.

In the example of FIG. 2B, PHYs 209A and 209B are not connected to a memory device. As such, PHYs 209A and 209B are unused. A memory device, such as PoP memory device 220, can be added to (e.g., soldered to the top of) SoC 202 at a later time. As such, FIGS. 2A and 2B illustrate that the same SiP 200 and, in particular, the same SoC 202 can be used in designs that prefer or require a POP memory device 220, as well as in designs that do not prefer or require the POP memory device 220. In some examples, and as described further herein, SoC 202 can disable (e.g., cut power to) PHYs 209A and 209B when not in use, such as in the configuration of FIG. 2B.

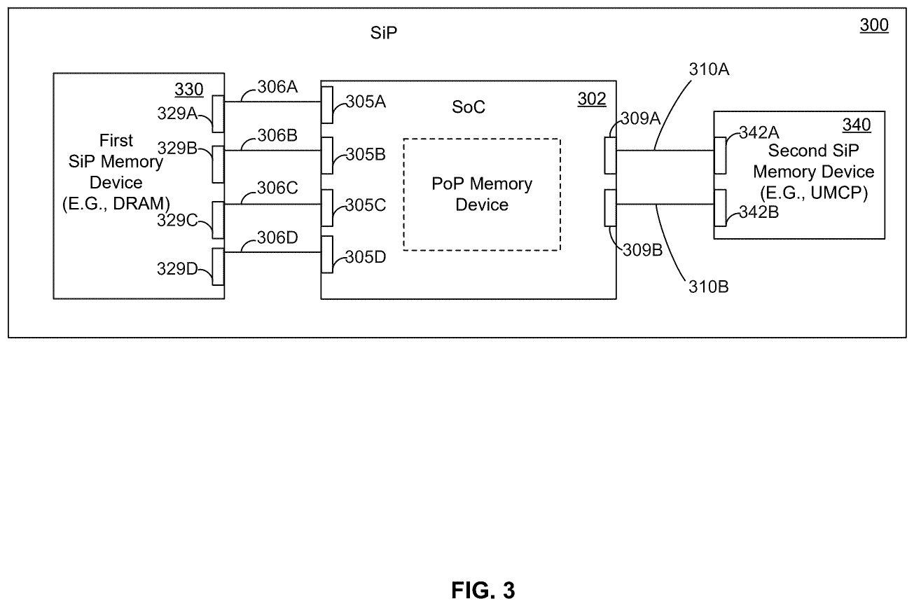

FIG. 3 illustrates a block diagram of a SiP 300 that includes SoC 302, first SiP memory device 330, and second SiP memory device 340. First SiP memory device 330 and second SiP memory device 340 can be the same, or different, types of memory devices. For instance, the first SiP memory device 330 may be a DRAM memory device, and the second SiP memory device 340 may be a uMCP memory device.

As illustrated, SiP 300 includes six physical layer interfaces that are electrically connected to first SiP memory device 330 and second SiP memory device 340, which are located within SiP 300. Specifically, PHY 305A of SoC 302 is electrically connected to a PHY 329A of first SiP memory device 330 over communication link 306A. Similarly, PHY 305B of SoC 302 is electrically connected to a PHY 329B of first SiP memory device 330 over communication link 306B, and PHY 305C of SoC 302 is electrically connected to a PHY 329C of first SiP memory device 330 over communication link 306A. Further, PHY 305D of SoC 302 is electrically connected to a PHY 329D of first SiP memory device 330 over communication link 306D. In addition, PHY 309A of SoC 302 is electrically connected to a PHY 342A of second SiP memory device 340 over communication link 310A. Similarly, PHY 309B of SoC 302 is electrically connected to a PHY 342B of second SiP memory device 340 over communication link 310B. As such, in this configuration, SoC 302 can communicate simultaneously with two SiP memory devices namely first SiP memory device 330 and second SiP memory device 340.

In some examples, rather than four communication channels, SoC 302 and first SiP memory device 330 may communicate over a lesser number of channels, such as two channels. The additional channels may be used to communicate with, for instance, a POP memory device 320 that be electrically connected to the top surface of SoC 302. For example, PHYs 305A and 305B may be electrically connected to the first SiP memory device 330 as illustrated, and PHYs 305C and 305D may be electrically connected to the POP memory device 320, rather than to the first SiP memory device 330. In this configuration, SoC 302 is able to simultaneously communicate with three memory devices.

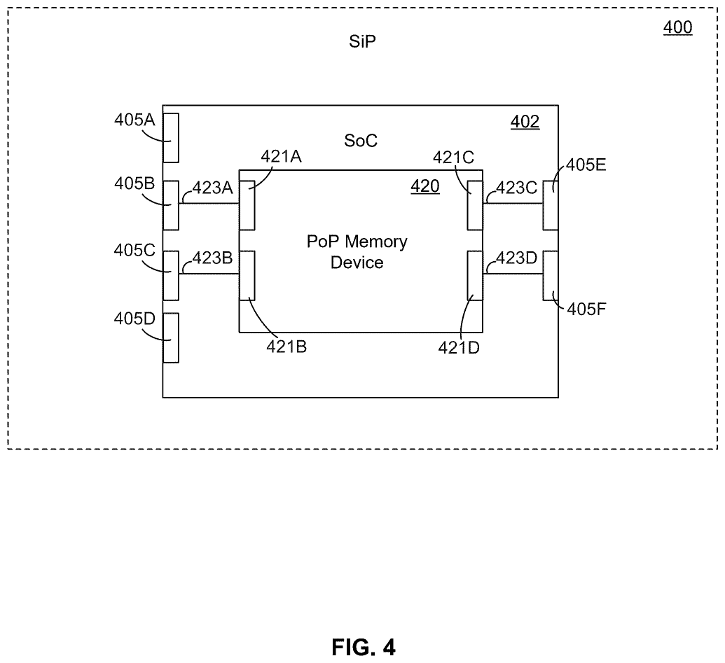

FIG. 4 illustrates an SoC 402 that, for instance, may be included within a SiP 400. In this example, SoC 402 includes multiple physical layer interfaces including PHY 405A, PHY 405B, PHY 405C, PHY 405D, PHY 405E, and PHY 405F. The physical layer interfaces may be configured to communicate over one or more communication channels. In this example, PHYs 405B, 405C, 405E, and 405F are electrically connected to POP memory device 420. Specifically, POP memory device 420 includes PHYs 421A, 421B, 421C, 421C, and 421D. The PHYs 405B, 405C, 405E, and 405F of SoC 402 are electrically connected by communication links 423A, 423B, 423C, 423D, respectively, to the PHYS 421A, 421B, 421C, 421C, and 421D of POP memory device 420, respectively. For instance, POP memory device 420 may be soldered to a top surface of SoC 402 such that PHYs 421A, 421B, 421C, 421C, and 421D are electrically connected to the communication links 423A, 423B, 423C, 423D. Communication links 423A, 423B, 423C, 423D may be, for instance, electrical traces or bond wires.

As described further herein, SoC 402 may disable PHYs 405A and 405D when not in use. In some examples, another memory device, such as a uMCP memory device, may be electrically connected to PHYs 405A and 405B, thereby allowing SoC 402 to communicate with an additional memory device.

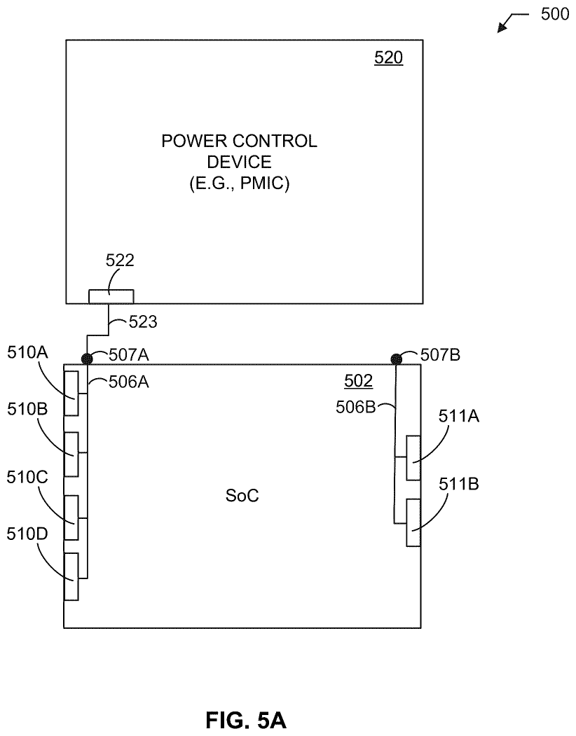

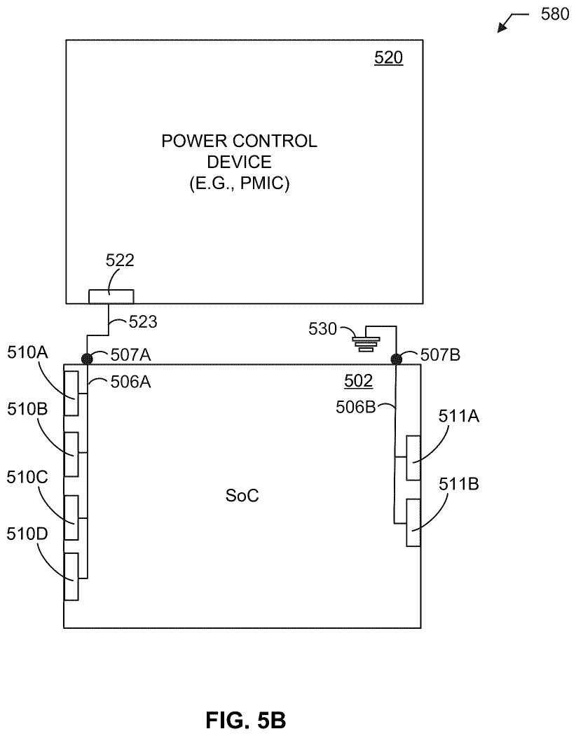

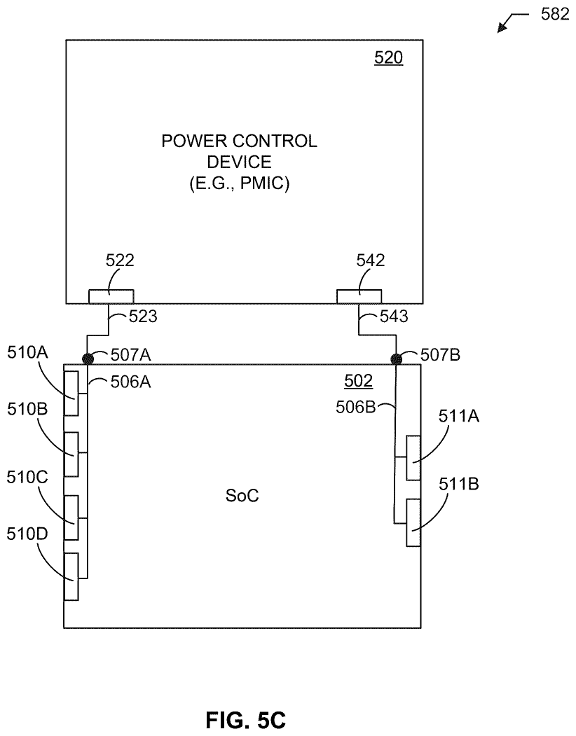

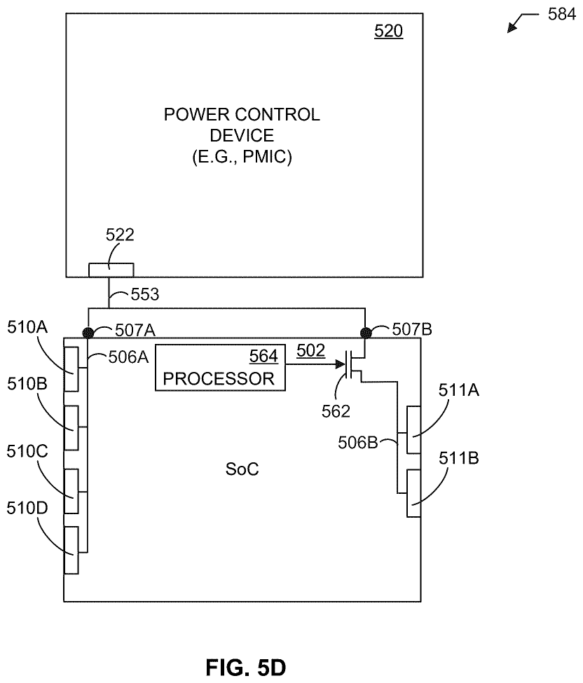

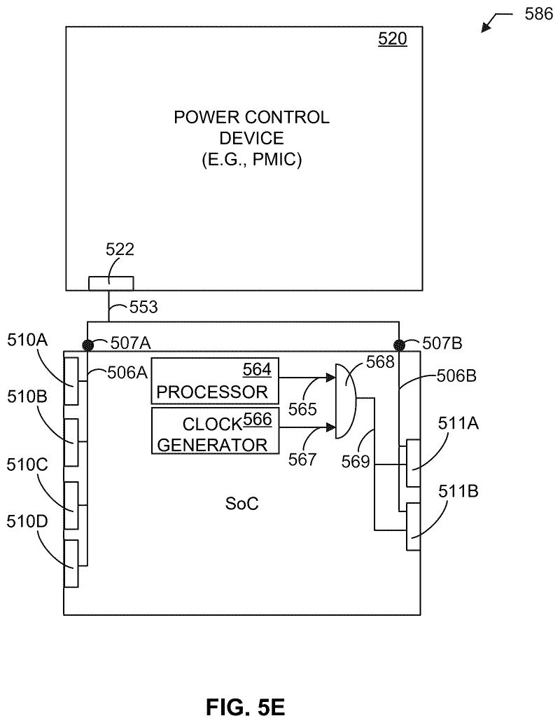

FIGS. 5A through 5E illustrate various configurations of an integrated circuit 500 that includes an SoC 502 electrically coupled to a power control device 520 (e.g., a PMIC), where the power control device 520 can provide power to the SoC 502. With reference to FIG. 5A, the SoC 502 includes multiple physical layer interfaces including PHYs 510A, 510B, 510C, 510D, 511A, and 511B. A power rail can provide power to each of the physical layer interfaces. Specifically, power rail 506A can provide power to PHYs 510A, 510B, 510C, 510D, and power rail 506B can provide power to PHYs 511A and 511B. The power rails may receive power from the power control device 520.

For example, power control device 520 may include one or more power regulators, such as power regulator 522, that can provide power to the SoC 502. In the example of FIG. 5A, power regulator 522 can provide power to power pin 507A of SoC 502 over power bus 523. The power pin 507A is electrically connected to the power rail 506A. As such, PHYs 510A, 510B, 510C, and 510D can receive power from the power regulator 522 of the power control device 520. PHYs 511A and 511B, however, receive power over power rail 506B. Power pin 507B, which is electrically connected to power rail 506B, is not connected to any regulator of the power control device 520. For instance, power pin 507B may be unconnected. As such, in this example, PHYs 511A and 511B are not powered, and thus are disabled.

FIG. 5B illustrates an alternate configuration whereby PHYs 510A, 510B, 510C, and 510D are still similarly powered by the power control device 520 and where PHYs 511A and 511B are not powered. However, rather than being disconnected, power pin 507B is electrically connected to ground. Thus, because PHYs 511A and 511B do not receive power, they are disabled.

In the configuration of FIG. 5C, power control device 520 includes an additional power regulator 542 that can provide power over an additional power bus 543 to the power pin 507B. As such, the additional power regulator 542 can provide power to the PHYs 511A and 511B. In some examples, the power control device 520 is configured to enable at least one of the power regulators 522, 542. For instance, in applications that require the use of PHYs 510A, 510B, 510C, and 510D, but not of PHYs 511A and 511B, the power control device 520 may enable the power regulator 522, but disable the power regulator 542. As such, while PHYs 510A, 510B, 510C, and 510D receive power from the power regulator 522 and, thus, can transfer data, the PHYs 511A, 511B do not receive power from the additional power regulator 542, and thus are disabled and cannot transfer data.

Further, in applications that require the use of PHYs 511A and 511B, but not of PHYs 510A, 510B, 510C, and 510D, the power control device 520 may disable the power regulator 522, but enable the power regulator 542. In addition, for applications that require the use of all of the physical layer interfaces including PHYs 510A, 510B, 510C, 510D, 511A, and 511B, the power control device 520 may enable both power regulators 522 and 542.

In some examples, SoC 502 may employ flood gating or power gating techniques to enable or disable power to the PHYs 510A, 510B, 510C, 510D, 511A, and 511B. For instance, in FIG. 5D, SoC 502 includes a processor 564 and block head switch (BHS) 562 that employ a power gating technique to control whether power is provided to PHYs 511A and 511B. In this example, the power regulator 522 of the power control device 520 provides power over a power bus 552 to both of the power pins 507A, 507B. The PHYs 510A, 510B, 510C, 510D receive power over the power rail 506A as described herein. The PHYs 511A and 511B, however, will receive power from the power rail 506B when the processor 564 enables the BHS 562 to pass the power received at the power pin 507B.

For example, processor 564 may, based on executing corresponding instructions, generate and transmit a first signal to the BHS 562, causing the BHS 562 to pass the power received from the power regulator 522 to the power rail 506B, and thus power the PHYs 511A, 511B. To prevent the PHYs 511A, 511B from receiving power, the processor may, based on executing corresponding instructions, provide a second signal to the BHS 562, which causes the BHS 562 to prevent power received from the power regulator 522 to pass to the power rail 506B. Although not illustrated for simplicity reasons, in some examples, the SoC 502 may include an additional BHS 562 that can be controlled by the processor 564 to allow, or disallow, power to the power rail 506A, thereby controlling whether the PHYs 510A, 510B, 510C, 510D receive power from the power control device 520.

In the configuration of FIG. 5E, SoC 502 employs a clock gating cell (CGC) technique to control when power is provided to PHYs 511A and 511B. As illustrated, SoC 502 includes, in addition to processor 564, a clock generator 566 and gating circuit 568. The gating circuit 568 may be or include, for example, an AND gate. The clock generator 566 is configured to provide a clock signal 567 to the gating circuit 568. Further, the processor 564 can, based on executing corresponding instructions, generate and transmit an enable signal 565 to the gating circuit 568. The gating circuit 568 is configured to provide the clock signal 567 over a clock bus 569 to each of the PHYs 511A, 511B based on the enable signal 565 received from the processor 564. For instance, assuming an “active high” configuration, the gating circuit 568 may provide the clock signal 567 to the clock bus 569 when the enable signal 565 is “high” (e.g., 3.3 Volts). The gating circuit 568 may not provide the clock signal 567 to the clock bus 569 when the enable signal 565 is “low” (e.g., 0 Volts). For instance, the gating circuit 568 may provide a low signal (e.g., 0 Volts) to the clock bus 569 when the enable signal 565 is “low.”

The signal provided on the clock bus 569 is used as the clock to the PHYs 511A, 511B. For example, as illustrated, the PHYs 511A, 511B receive power on the power rail 506B from the regulator 553 of the power control device 520. Thy PHYs 511A, 511B can transfer data based on the clock signal 567 received on the clock bus 569. As such, assuming that the processor 564 is providing an enable signal 565 (e.g., 3.3 Volts) to the gating circuit 568 that allows the gating circuit 568 to pass the clock signal 567, the PHYs 511A, 511B can transfer data based on the clock signal 567. If, however, the processor 564 is providing an enable signal 565 (e.g., 0 Volts) to the gating circuit 568 that does not allow the gating circuit 568 to pass the clock signal 567, then the PHYs 511A, 511B are not able to transfer data as their clock is disabled. Although not illustrated for simplicity reasons, in some examples, the SoC 502 may include an additional gating circuit 568 that can be controlled by the processor 564 to pass a clock signal to the PHYs 510A, 510B, 510C, 510D, thereby similarly enabling or disabling data transfers on PHYs 510A, 510B, 510C, 510D.

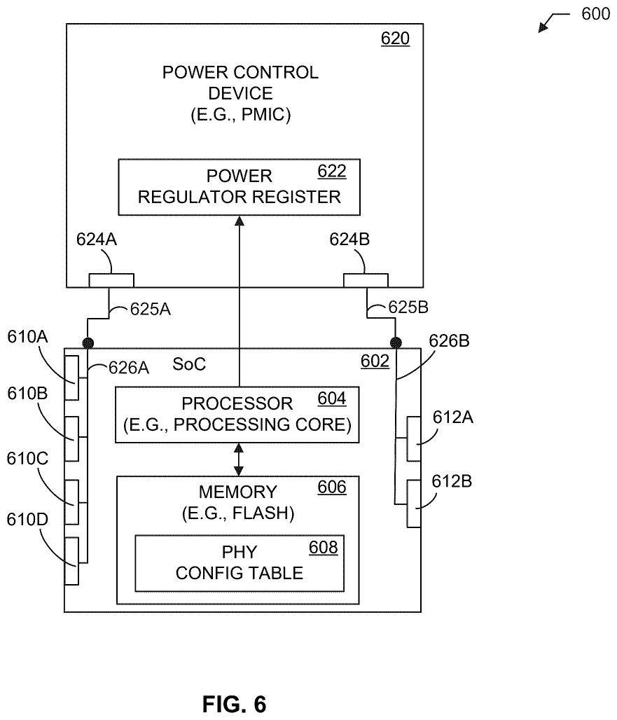

FIG. 6 illustrates an SoC 602 that includes a processor 604, memory device 606, PHYs 610A, 610B, 610C, 610D, and PHYs 612A and 612B. PHYs 610A, 610B, 610C, 610D receive power over a power rail 626A, and PHYs 612A, 612B receive power over a power rail 626B. The memory device 606 includes a PHY configuration table 608 that can be read and adjusted by processor 604. Further, the PHY configuration table 608 includes data characterizing whether each of the PHYs 610A, 610B, 610C, 610D, PHYs 612A and 612B are to be enabled, or disabled. For instance, the PHY configuration table 608 may include at least one bit for each of the physical layer interfaces, where a first value (e.g., 1) indicates a particular physical interface layer should be enabled, and a second value (e.g., 0) indicates the particular physical interface layer should be disabled.

As further illustrated in FIG. 6, a power control device 620 (e.g., PMIC) includes a power regulator register 622 that controls whether a first power regulator 624A and a second power regulator 624B of the power control device 620 are enabled. The first power regulator 624A, when enabled, provides power over power bus 625A to a power pin 607A of the SoC 602. The power pin 607A is electrically connected to the power rail 626A that can provide power to PHYs 610A, 610B, 610C, and 610D. Similarly, the second power regulator 624B, when enabled, provides power over power bus 625B to a power pin 607B of the SoC 602. The power pin 607B is electrically connected to the power rail 626B that can provide power to PHYs 611A and 611B.

To enable or disable the power regulators 624A, 624, the processor 604 may read the PHY configuration table 608 stored within the memory device 606 to determine whether the PHYs 610A, 610B, 610C, 610D, PHYs 612A and 612B are to be enabled. Based on the read data, the processor 604 may generate power regulator data 605 characterizing whether the first power regulator 624A and the second power regulator 624B should be enabled or disabled. Processor 604 may transmit the power regulator data 605 to the power control device 620 to write to the power regulator register 622, thereby enabling or disabling the first power regulator 624A and the second power regulator 624B accordingly.

For example, processor 604 may determine, based on the PHY configuration table 608, that PHYs 610A, 610B, 610C, and 610D are to be enabled, and PHYs 611A and 611B are to be disabled. As such, processor 604 may generate the power regulator data 605 to enable the first power regulator 624A which provides power to the PHYs 610A, 610B, 610C, and 610D, and to disable and the second power regulator 624B, which provides power to the PHYs 611A, 611B.

In some examples, processor 604 may generate the power regulator data 605 to enable a power regulator 624A, 624B if at least one physical interface layer powered by the power regulator 624A, 624B is to be enabled, even if others powered by the same power regulator 624A, 624 are to be disabled. For instance, processor 604 may determine, based on the PHY configuration table 608, that PHYs 610A and 610B are to be enabled, and PHYs 610C, 610D, 611A, and 611B are to be disabled. In such a case, processor 604 still generates the power regulator data 605 to enable the first power regulator 624A which provides power to the PHYs 610A and 610B, even though it may provide power to PHYs 610C and 610D. Processor 604 also generates the power regulator data 605 to disable the second power regulator 624B, which can provide power to the PHYs 611A, 611B, thereby disabling the PHYs 611A, 611B.

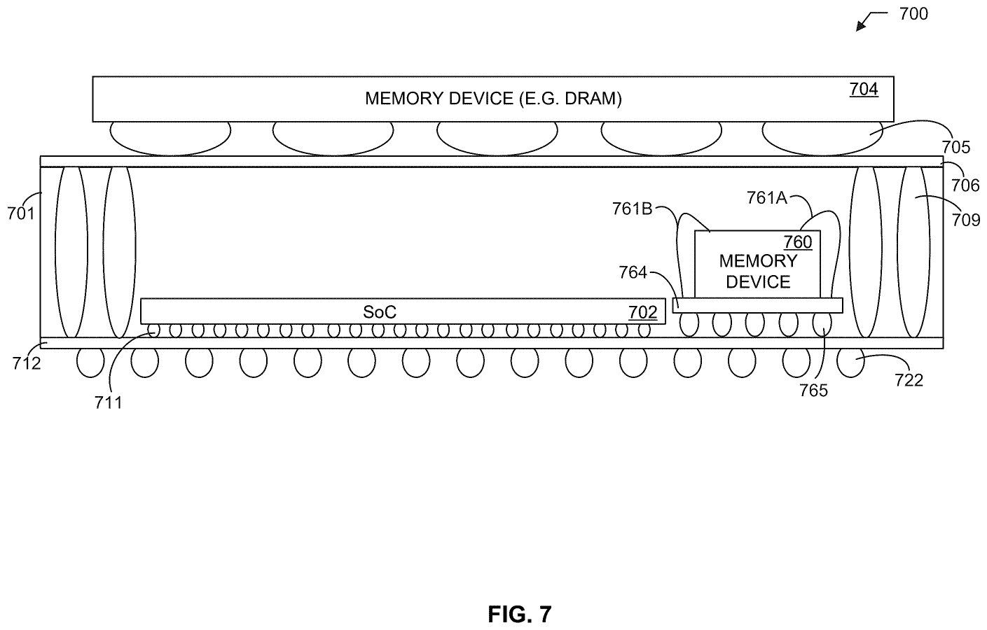

FIG. 7 illustrates a device 700 that includes a wafer 701 with an SoC 702 electrically connected to a POP memory device 704 and to a SiP memory device 760. The SoC 702 and the SiP memory device 760 are positioned between a first substrate 706 and a second substrate 712. The support structures 709 separate the first substrate 706 from the second substrate 712. The SoC 702 includes electrical connectors 711 (e.g., pins, solder balls) that are attached to a top surface of the second substrate 712. The electrical connectors 711 can connected to electrical traces that can route signals to and from the SoC 702. The wafer 701 also includes pins 722 (e.g., solder balls) that can attach (e.g., be soldered), for example, to a printed circuit board (PCB).

The POP memory device 704 is positioned on a top surface of the first substrate 706, and can be electrically connected to the SoC 702 through one or more electrical connections. The PoP memory device 704 may be any suitable memory device, such as a DRAM or FLASH device. The POP memory device 704 includes solder balls 705 whereby one or more of the solder balls 705 may be electrically connected to traces (e.g., via electrical pads) that route to the SoC 702.

The SiP memory device 760 may be in a side-by-side configuration with the SoC 702, and includes a SiP substrate 764 positioned on electrical connectors 765. One or more electrical traces may proceed through or along the second substrate 712 from one or more of the electrical connectors 711 of the SoC to one or more of the electrical connectors 765 of the SiP memory device 760. The SiP memory device 760 may also include bond wires 761A, 761B, which may route additional signals from the SiP memory device 760 to the SiP substrate 764.

In some examples, SoC 702 includes multiple physical interface layers, such as PHYs 610A, 610B, 610C, 610D, that are electrically connected to the POP memory device 704 (e.g., via bond wires, electrical traces). The SoC 702 may additionally include multiple physical interface layers, such as PHYs 611A, 611B, that are electrically connected to the SiP memory device 760 (e.g., via bond wires, electrical traces). As such, the SoC 702 can simultaneously communicate with each of the POP memory device 704 and SiP memory device 760. In some examples, SoC 702 may enable and disable any of these physical interface layers as described herein.

Implementation examples are further described in the following numbered clauses:

1. A die package comprising:
a first memory device; and
a system-on-a-chip (SoC), comprising:
   a first plurality of physical layer interfaces electrically connected to the first memory device, wherein the SoC and the first memory device are in a first die package configuration; and
   a second plurality of physical layer interfaces configured to electrically connect to a second memory device, wherein the SoC and the second memory device are in a second die package configuration.

2. The die package of clause 1, wherein the first die package configuration is package-on-package (POP).

3. The die package of clause 2, wherein the first memory device is positioned on a top surface of the SoC.

4. The die package of any clauses 1-3, wherein the second die package configuration is system-in-a-package (SiP).

5. The die package of any of clauses 1-4, wherein the first plurality of physical layer interfaces comprise at least four physical layer interfaces.

6. The die package of any of clauses 1-5, wherein the second plurality of physical layer interfaces comprise at least two physical layer interfaces.

7. The die package of any of clauses 1-6, wherein the second plurality of physical layer interfaces are electrically connected to the second memory device.

8. The die package of any of clauses 1-7, wherein the SoC is configured to:
transfer data with the first memory device using each of the first plurality of physical layer interfaces; and
transfer data with the second memory device using the second plurality of physical layer interfaces.

9. A die package comprising:
a first memory device;
a second memory device; and
a system-on-a-chip (SoC), the SoC comprising:
   a first plurality of physical layer interfaces electrically connected to the first memory device, wherein the SoC and the first memory device are in a first die package configuration;
   a second plurality of physical layer interfaces electrically connected to the second memory device, wherein the SoC and the second memory device are in a second die package configuration; and
   at least one power rail configured to provide power to the first plurality of physical layer interfaces and the second plurality of physical layer interfaces.

10. The die package of clause 9, wherein the first die package configuration is package-on-package (POP).

11. The die package of any of clauses 9-10, wherein the first memory device is positioned on a top surface of the SoC.

12. The die package of any of clauses 9-11, wherein the second die package configuration is system-in-a-package (SiP).

13. The die package of any of clauses 9-12, wherein the first plurality of physical layer interfaces comprise at least four physical layer interfaces.

14. The die package of any of clauses 9-13, wherein the second plurality of physical layer interfaces comprise at least two physical layer interfaces.

15. The die package of any of clauses 9-14, wherein the SoC is configured to:
transfer data with the first memory device using each of the first plurality of physical layer interfaces; and
transfer data with the second memory device using the second plurality of physical layer interfaces.

16. The die package of any of clauses 9-15 comprising a processor and a block head switch configured to allow the power on the at least one power rail, wherein the processor is configured to transmit a signal to the block head switch, and the block head switch is configured to allow the power on the at least one power rail based on the signal.

17. The die package of any of clauses 9-16 comprising a processor, a clock generator configured to generate a clock signal, and a gating circuit configured to provide the clock signal to at least one of: the first plurality of physical layer interfaces and the second plurality of physical layer interfaces, wherein:
the processor is configured to transmit an enable signal to the gating circuit; and
the gating circuit is configured provide the clock signal based on the enable signal.

18. A system-on-a-chip (SoC) comprises:
a first plurality of physical layer interfaces configured to electrically connect to a first memory device when the SoC and the first memory device are in a first die package configuration;
a second plurality of physical layer interfaces configured to electrically connect to a second memory device when the SoC and the second memory device are in a second die package configuration; and
a processor configured to generate and transmit power regulator data to a power control device, the power regulator data causing the power control device to enable power to at least one of the first plurality of physical layer interfaces and the second plurality of physical layer interfaces.

19. The SoC of clause 18, wherein the first die package configuration is package-on-package (POP).

20. The SoC of any of clauses 18-19, wherein the first memory device is positioned on a top surface of the SoC.

21. The SoC of any of clauses 18-20, wherein the second die package configuration is system-in-a-package (SiP).

22. The SoC of any of clauses 18-21, wherein the first plurality of physical layer interfaces comprise at least four physical layer interfaces.

23. The SoC of any of clauses 18-22, wherein the second plurality of physical layer interfaces comprise at least two physical layer interfaces.

24. The SoC of any of clauses 18-23, wherein the second plurality of physical layer interfaces are electrically connected to the second memory device.

25. The SoC of any of clauses 18-124, wherein the SoC is configured to:
transfer data with the first memory device using each of the first plurality of physical layer interfaces; and
transfer data with the second memory device using the second plurality of physical layer interfaces.

26. The SoC of any of clauses 18-25, wherein the first plurality of physical layer interfaces comprise at least four physical layer interfaces.

27. The SoC of any of clauses 18-26, wherein the second plurality of physical layer interfaces comprise at least two physical layer interfaces.

28. The SoC of any of clauses 18-27 comprising at least one power rail configured to provide the power to the first plurality of physical layer interfaces and the second plurality of physical layer interfaces.

Although the methods described above are with reference to the illustrated flowcharts, many other ways of performing the acts associated with the methods may be used. For example, the order of some operations may be changed, and some embodiments may omit one or more of the operations described and/or include additional operations.

In addition, the methods and system described herein may be at least partially embodied in the form of computer-implemented processes and apparatus for practicing those processes. The disclosed methods may also be at least partially embodied in the form of tangible, non-transitory machine-readable storage media encoded with computer program code that, when executed, causes a machine to fabricate at least one integrated circuit that performs one or more of the operations described herein. For example, the methods may be embodied in hardware, in executable instructions executed by a processor (e.g., software), or a combination of the two. The media may include, for example, RAMs, ROMs, CD-ROMs, DVD-ROMs, BD-ROMs, hard disk drives, flash memories, or any other non-transitory machine-readable storage medium. When the computer program code is loaded into and executed by a computer, the computer becomes an apparatus for causing a machine to fabricate the integrated circuit. The methods may also be at least partially embodied in the form of a computer into which computer program code is loaded or executed, such that, the computer becomes a special purpose computer for causing a machine to fabricate the integrated circuit. For instance, when implemented on a general-purpose processor, computer program code segments can configure the processor to create specific logic circuits. The methods may alternatively be at least partially embodied in application specific integrated circuits or any other integrated circuits for performing the methods.

In addition, terms such as “circuit,” “circuitry,” “logic,” and the like can include, alone or in combination, analog circuitry, digital circuitry, hardwired circuitry, programmable circuitry, processing circuitry, hardware logic circuitry, state machine circuitry, and any other suitable type of physical hardware components. Further, the embodiments described herein may be employed within various types of devices such as networking devices, telecommunication devices, smartphone devices, gaming devices, enterprise devices, storage devices (e.g., cloud storage devices), and computing devices (e.g., cloud computing devices), among other types of devices.

The subject matter has been described in terms of exemplary embodiments. Because they are only examples, the claimed inventions are not limited to these embodiments. Changes and modifications may be made without departing the spirit of the claimed subject matter. It is intended that the claims cover such changes and modifications.

We claim:

1. A die package comprising:
a first memory device; and
a system-on-a-chip (SoC), comprising:
a first plurality of physical layer interfaces electrically connected to the first memory device, wherein the SoC and the first memory device are in a first die package configuration; and
a second plurality of physical layer interfaces configured to electrically connect to a second memory device, wherein the SoC and the second memory device are in a second die package configuration.

2. The die package of claim 1, wherein the first die package configuration is package-on-package (POP).

3. The die package of claim 2, wherein the first memory device is positioned on a top surface of the SoC.

4. The die package of claim 1, wherein the second die package configuration is system-in-a-package (SiP).

5. The die package of claim 1, wherein the first plurality of physical layer interfaces comprise at least four physical layer interfaces.

6. The die package of claim 1, wherein the second plurality of physical layer interfaces comprise at least two physical layer interfaces.

7. The die package of claim 1, wherein the second plurality of physical layer interfaces are electrically connected to the second memory device.

8. The die package of claim 1, wherein the SoC is configured to:
transfer data with the first memory device using each of the first plurality of physical layer interfaces; and
transfer data with the second memory device using the second plurality of physical layer interfaces.

9. A die package comprising:
a first memory device;
a second memory device; and
a system-on-a-chip (SoC), the SoC comprising:
a first plurality of physical layer interfaces electrically connected to the first memory device, wherein the SoC and the first memory device are in a first die package configuration;
a second plurality of physical layer interfaces electrically connected to the second memory device, wherein the SoC and the second memory device are in a second die package configuration; and
at least one power rail configured to provide power to the first plurality of physical layer interfaces and the second plurality of physical layer interfaces.

10. The die package of claim 9, wherein the first die package configuration is package-on-package (POP).

11. The die package of claim 9, wherein the first memory device is positioned on a top surface of the SoC.

12. The die package of claim 9, wherein the first plurality of physical layer interfaces comprise at least four physical layer interfaces, and the second plurality of physical layer interfaces comprise at least two physical layer interfaces.

13. The die package of claim 9, wherein the SoC is configured to:
transfer data with the first memory device using each of the first plurality of physical layer interfaces; and
transfer data with the second memory device using the second plurality of physical layer interfaces.

14. The die package of claim 9 comprising a processor and a block head switch configured to allow the power on the at least one power rail, wherein the processor is configured to transmit a signal to the block head switch, and the block head switch is configured to allow the power on the at least one power rail based on the signal.

15. The die package of claim 9 comprising a processor, a clock generator configured to generate a clock signal, and a gating circuit configured to provide the clock signal to at least one of: the first plurality of physical layer interfaces and the second plurality of physical layer interfaces, wherein:
the processor is configured to transmit an enable signal to the gating circuit; and
the gating circuit is configured provide the clock signal based on the enable signal.

16. A system-on-a-chip (SoC) comprises:
a first plurality of physical layer interfaces configured to electrically connect to a first memory device when the SoC and the first memory device are in a first die package configuration;
a second plurality of physical layer interfaces configured to electrically connect to a second memory device when the SoC and the second memory device are in a second die package configuration; and
a processor configured to generate and transmit power regulator data to a power control device, the power regulator data causing the power control device to enable power to at least one of the first plurality of physical layer interfaces and the second plurality of physical layer interfaces.

17. The SoC of claim 16, wherein the first die package configuration is package-on-package (POP).

18. The SoC of claim 16, wherein the SoC is configured to:
transfer data with the first memory device using each of the first plurality of physical layer interfaces; and
transfer data with the second memory device using the second plurality of physical layer interfaces.

19. The SoC of claim 16, wherein the first plurality of physical layer interfaces comprise at least four physical layer interfaces, and the second plurality of physical layer interfaces comprise at least two physical layer interfaces.

20. The SoC of claim 16 comprising at least one power rail configured to provide the power to the first plurality of physical layer interfaces and the second plurality of physical layer interfaces.
